(19) United States
(12) Patent Application Publication
(10) Pub. No.: US 2026/0223518 A1
(43) Pub. Date: Jul. 30, 2026

(54) THROUGH-HOLE CONTACT PORTION FOR MICRO-LED AND METHOD FOR FORMING THE SAME

(71) Applicant: Hue Inc., Shanghai (CN)

(72) Inventor: Feng Feng, Shanghai (CN)

(73) Assignee: Hue Inc., Shanghai (CN)

(21) Appl. No.: 19/458,929

(22) Filed: Jan. 26, 2026

(30) Foreign Application Priority Data
Jan. 26, 2025 (CN) 202510124085.2

(51) Int. Cl. H10H 29/85; H10H 20/831

(52) U.S. Cl. CPC H10H 29/857; H10H 20/831

(57) ABSTRACT

The present disclosure provides a through-hole contact portion for a micro-LED, wherein the through-hole contact portion is configured to electrically connect a first conductive structure with a second conductive structure, wherein the first conductive structure is located below the through-hole contact portion and the second conductive structure is located above the through-hole contact portion, wherein the through-hole contact portion includes: a through-hole formed in an insulating layer and having a hollow cavity; filling metal arranged in the hollow cavity of the through-hole for conducting electricity; and a first metal barrier layer arranged between the bottom of the through-hole and the first conductive structure and/or between the top of the through-hole and the second conductive structure to block diffusion of the filling metal. Furthermore, the present disclosure also provides a method for forming the through-hole contact portion.

### CROSS-REFERENCE TO RELATED APPLICATION

This application claims the priority benefit of China application serial no. 202510124085.2, filed on January 26, 2025. The entirety of the above-mentioned patent application is hereby incorporated by reference herein and made a part of this specification.

### BACKGROUND

### Technical Field

The present disclosure generally relates to the field of Micro light emitting diode (micro-LED), and more specifically relates to a through-hole contact portion for a micro-LED and a method for forming the same. Furthermore, the present disclosure also relates to a micro-LED chip having such a through-hole contact portion.

### Description of Related Art

Micro-LED is a new type LED structure obtained by thin-filming, miniaturizing, and arraying the original LED structure, which integrates the arrayed micro level micro-LEDs on an active addressing drive panel to achieve the lighting and individual control of the micro-LEDs, thereby outputting the desired display image. The core structure of the micro-LED is a PN junction diode composed of direct-bandgap semiconductor material. When the upper and lower electrodes apply a forward bias voltage to the micro-LED to allow current to pass through, electrons and holes recombine in the active area, and meanwhile emit monochromatic light photons.

The through-hole contact portion is an important conductive structure in the LED chip, for example, it is used to electrically connect the light-emitting mesa of the micro-LED with the drive circuit below the insulation layer by passing through the insulation layer. Metal used for conducting electricity, such as copper, is deposited in the through-hole contact portion, but the metal may diffuse in the chip, for example, it enters semiconductor structures such as the active area, the insulating layer, etc., so that the performance of related semiconductor structures is affected. The sidewall of the through-hole contact portion is typically deposited with metal, but there may still be metal diffusion at its two ends, for example, it diffuses into other structures through the conductive structures at two ends, particularly when the alignment between the through-hole contact portion and the conductive structures below it is poor, the consequences of metal diffusion are particularly severe.

Currently, there is a need for a through-hole contact portion that can suppress metal diffusion.

### SUMMARY

One aspect of the present disclosure provides a through-hole contact portion for a micro-LED and a micro-LED chip having such a through-hole contact portion, through the through-hole contact portion or the micro-LED chip, the method, metal diffusion in the through-hole contact portion can be effectively suppressed.

In a first aspect of the present disclosure, the aforementioned task is achieved by a through-hole contact portion for a micro-LED, where the through-hole contact portion is configured to electrically connect a first conductive structure with a second conductive structure, where the first conductive structure is located below the through-hole contact portion and the second conductive structure is located above the through-hole contact portion, where the through-hole contact portion includes:

a through-hole formed in an insulating layer and having a hollow cavity;

filling metal arranged in the hollow cavity of the through-hole for conducting electricity; and

a first metal barrier layer arranged between the bottom of the through-hole and the first conductive structure and/or between the top of the through-hole and the second conductive structure to block diffusion of the filling metal.

In one embodiment of the present disclosure, the width of the first metal barrier layer is greater than the width of the bottom of the through-hole.

In another embodiment of the present disclosure, the through-hole contact portion further includes:

a second metal barrier layer arranged between the inner wall of the through-hole and the filling metal.

In another embodiment of the present disclosure, the diameter of the through-hole is 0.2 to 1 μm, and the height is 2 to 5 μm.

In another embodiment of the present disclosure, the filling metal is selected from one or more of the following:

copper, gold, silver, and tin.

In another embodiment of the present disclosure, the first metal barrier layer and/or the second metal barrier layer include:

a first metal layer including a plurality of stacked layers of a titanium layer and a platinum layer, where the titanium layer and the platinum layer are arranged alternately with each other; and

a second metal layer made of titanium.

In another embodiment of the present disclosure, the number of the stacked layers is 1 to 5.

In another embodiment of the present disclosure, it is provided that:

the thickness of the titanium layer is 100 to 300 angstroms; and/or

the thickness of the platinum layer is 100 to 300 angstroms; and/or

the thickness of the second metal layer is 200 to 400 angstroms.

In another embodiment of the present disclosure, the through-hole contact portion further includes:

a passivation layer arranged between the through-hole and the first conductive structure and/or the second conductive structure and exposing the first metal barrier layer.

In another embodiment of the present disclosure, it is provided that:

the breakdown field strength of the passivation layer is not less than 1x107 V/cm; or

the breakdown field strength of the passivation layer is not less than 6×108 V/cm.

In another embodiment of the present disclosure, the material of the passivation layer is selected from a group including the following items:

silicon nitride, aluminum oxide, silicon dioxide, and combinations of silicon nitride and aluminum oxide.

In another embodiment of the present disclosure, the passivation layer is deposited at a temperature T, where T = 100°C to 300°C.

In another embodiment of the present disclosure, the ratio of the cross-sectional length of the first metal barrier layer to the diameter of the through-hole is 1.2 to 1.8.

In another embodiment of the present disclosure, the offset between the centerline of the through-hole and the centerline of the first conductive structure is 0.1 to 0.3 μm.

In another embodiment of the present disclosure, the through-hole contact portion is configured to electrically connect the light-emitting mesa with the drive circuit.

In a second aspect of the present disclosure, the aforementioned task is solved by a micro-LED chip, which includes:

a plurality of micro-LEDs, where each micro-LED includes a light-emitting mesa arranged on a drive circuit and configured to emit a first light;

a drive circuit; and

the through-hole contact portion according to the present disclosure, which is configured to electrically connect the light-emitting mesa with the drive circuit.

In one embodiment of the present disclosure, it is provided that:

a metal layer is arranged on the surface of the drive circuit, and a plurality of through-hole contact portions are arranged on the drive circuit, and the through-hole contact portions are electrically connected with the metal layer, and the micro-LEDs are bonded onto the drive circuit through a bottom conductive bonding layer, and each light-emitting mesa corresponds to one of the through-hole contact portions, and the light-emitting mesa includes a first epitaxial layer, a light-emitting layer, and a second epitaxial layer deposited in sequence; and

the micro-LED further includes:

a first electrode electrically connected with the through-hole contact portions;

a passivation isolation layer covering the surface of the light-emitting mesa but exposing at least a part of the second epitaxial layer;

a transparent conductive layer arranged on the surface of the passivation isolation layer and in electrical contact with the first epitaxial layer; and

a second electrode arranged on the surface of the transparent conductive layer.

In another embodiment of the present disclosure, the second electrode is a ring-shaped reflective electrode arranged around the light-emitting mesa.

In another embodiment of the present disclosure, the polarity of the second electrode is opposite to the polarity of the first electrode.

In another embodiment of the present disclosure, the material of the second epitaxial layer is a material layer of a second conductivity type including two or more elements of Ga, N, As, Al, In, and P, and the first epitaxial layer is a material layer of a first conductivity type including at least two or more elements of Ga, N, As, Al, In, and P, where the first conductivity type is different from the second conductivity type.

In another embodiment of the present disclosure, the light-emitting layer includes a multi-quantum-well layer, where the multi-quantum-well layer is an InGaN/GaN multi-quantum-well layer, an InGaN/AlGaN multi-quantum-well layer, an InGaAs/AlGaAs multi-quantum-well layer, or an AlGaInP multi-quantum-well layer.

In another embodiment of the present disclosure, a first side of the light-emitting layer has an electron blocking layer, and the first side is a side along which electrons migrate out of the light-emitting layer.

In another embodiment of the present disclosure, the material of the metal layer is an alloy of one or more of the following metals: Ni, Al, Ti, Ni, Pt, Au.

In another embodiment of the present disclosure, the material of the passivation isolation layer is a Si₃N₄ film, a SiO₂ film, or an Al₂O₃ film.

In a third aspect of the present disclosure, the aforementioned task is solved by a micro-LED chip, the micro-LED chip includes:

an upper stacked layer, which includes:

a first insulating layer configured to accommodate a light-emitting mesa and a first through-hole contact portion;

a light-emitting mesa configured to emit light, where the top surface area of the light-emitting mesa is greater than the bottom surface area of the light-emitting mesa; and

a first through-hole contact portion constructed according to the present disclosure and electrically connected with the bottom of the light-emitting mesa and passing through the first insulating layer; and

a lower stacked layer, which includes:

a second insulating layer configured to accommodate a second through-hole contact portion;

a second through-hole contact portion constructed according to the present disclosure and passing through the second insulating layer; and

a drive backplane electrically connected with the second through-hole contact portion, where the lower stacked layer is bonded with the upper stacked layer through hybrid bonding, such that the first through-hole contact portion is bonded with the second through-hole contact portion and the first insulating layer is bonded with the second insulating layer.

In a fourth aspect of the present disclosure, the aforementioned task is solved by a method for forming a through-hole contact portion, the method includes the following steps:

providing a first conductive structure;

forming a passivation layer on the first conductive structure;

removing a part of the passivation layer to expose the first conductive structure;

forming a first metal barrier layer on the exposed first conductive structure;

forming an insulating layer on the passivation layer and the first metal barrier layer;

etching the insulating layer to form through-hole, where the bottom of the through-hole is opposed to the first metal barrier layer; and

depositing filling metal in the through-hole.

In one embodiment of the present disclosure, the method further includes the following steps:

before depositing metal in the through-hole, forming a second metal barrier layer on the inner wall of the through-hole.

In another embodiment of the present disclosure, the method further includes the following steps:

forming a first metal barrier layer at the top of the through-hole; and

forming a third conductive structure on the first metal barrier layer.

The present disclosure has at least the following beneficial effects:

(1) In the present disclosure, by arranging a metal barrier layer between the bottom and/or top of the through-hole contact portion and the conductive structure electrically connected with it, the present disclosure can substantially prevent metal diffusion from the through-hole contact portion into the corresponding conductive structure, particularly, it effectively prevents metal from first diffusing from the through-hole contact portion into the conductive structure electrically connected with it and then further diffusing from the conductive structure into other structures;

(2) In the present disclosure, by first forming the metal barrier layer on the conductive structure electrically connected with the through-hole contact portion, then forming the through-hole contact portion on the metal barrier layer, and ensuring the area of the metal barrier layer is greater than the bottom area of the through-hole, in this way, compared with forming through-hole first and then forming a metal barrier layer at the bottom of the through-hole, it can ensure that the metal barrier layer completely covers the bottom of the through-hole without the existence of incomplete coverage of the metal barrier layer (which is possible in the case of forming the through-hole first and then forming a metal barrier layer at the bottom of the through-hole), so that metal diffusion is completely avoided, and even if the through-hole contact portion is misaligned with the conductive structure, as long as the through-hole is still within the range of the metal barrier layer, metal diffusion can still be completely prevented;

(3) The disclosure improves the material and structure of the metal barrier layer by using combinations of a plurality of titanium-platinum stacked layers plus a titanium layer, and metal diffusion in the through-hole contact portion can be better prevented.

### BRIEF DESCRIPTION OF THE DRAWINGS

The present disclosure is further explained below with reference to the accompanying drawings in conjunction with specific implementations.

FIG. 1 illustrates a schematic diagram of a first embodiment of a through-hole contact portion for a micro-LED according to the present disclosure.

FIG. 2 illustrates a schematic diagram of a second embodiment of a through-hole contact portion for a micro-LED according to the present disclosure.

FIG. 3 illustrates a schematic diagram of a third embodiment of a through-hole contact portion for a micro-LED according to the present disclosure.

FIGS. 4A-4E illustrate a first embodiment of a method for forming a through-hole contact portion according to the present disclosure.

FIGS. 5A-5D illustrate a second embodiment of a method for forming a through-hole contact portion according to the present disclosure.

### DESCRIPTION OF THE EMBODIMENTS

It should be noted that various components in the accompanying drawings may be exaggerated for the purpose of illustrative illustration and are not necessarily true to scale. In the accompanying drawings, components that are identical or functionally identical are provided with the same accompanying drawing reference signs.

In the present disclosure, unless otherwise specified, the words "arranged on", "arranged above" and "arranged over" do not exclude the existence of intermediates between the two. Furthermore, "arranged on or above" merely indicates the relative positional relationship between the two components, but under certain circumstances, such as when the product direction is reversed, it can be converted to "arranged under or below", and vice versa.

In the present disclosure, the embodiments are merely intended to illustrate the scheme of the present disclosure and should not be construed as limiting.

In the present disclosure, the quantifiers "a" and "one" do not exclude scenarios with a plurality of elements, unless otherwise specified.

In the present disclosure, the term "connect" may refer to either the two being directly connected or the two being indirectly connected through an intermediate component.

In the present disclosure, the term "configure" refers to the setting of the shape, structure, material, and/or function of a target object to achieve a desired technical effect, where "configure" includes various alternative technical means to achieve this technical effect, and these technical means become apparent under the teachings of the present disclosure.

It should also be noted herein that in embodiments of the present disclosure, merely a part of the components or assemblies may be shown for the sake of clarity and simplicity, but those ordinary skilled in the art will be able to understand that the required components or assemblies may be added as needed according to specific scenarios in light of the teachings of the present disclosure. Furthermore, features in different embodiments of the present disclosure may be combined with each other unless otherwise indicated. For example, a feature in the second embodiment may be substituted for a corresponding or functionally identical or similar feature in the first embodiment, and the obtained embodiment likewise falls within the scope of the disclosure or the scope of the record of the present application.

It should also be noted that, within the scope of the present disclosure, the terms "the same", "equal", "equal to", etc. do not mean that the two numerical values are absolutely equal, but rather allow for a certain reasonable error, that is to say, the terms also cover "substantially the same ", "substantially equal " and "substantially equal to". By analogy, in the present disclosure, the terms "perpendicular to", "parallel to", etc., which indicate direction, also cover the meaning of "substantially perpendicular to", "substantially parallel to".

In the present disclosure, the term "configure" refers to the setting of the shape, structure, material, and/or function of a target object to achieve a desired technical effect, where "configure" includes various alternative technical means to achieve this technical effect, these technical means become apparent under the teachings of the present disclosure.

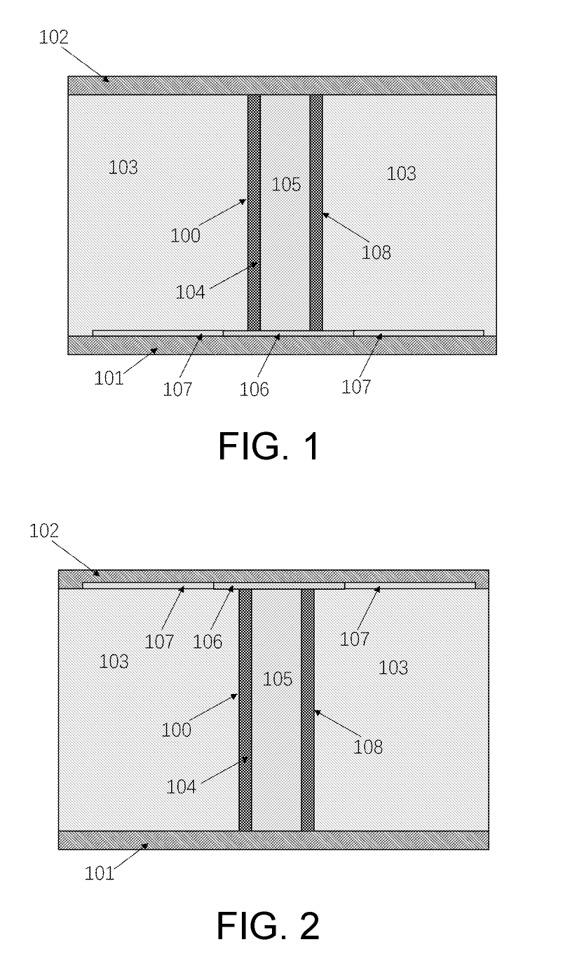

FIG. 1 illustrates a schematic diagram of a first embodiment of a through-hole contact portion 100 for a micro-LED according to the present disclosure.

As shown in FIG. 1, the through-hole contact portion 100 for a micro-LED according to the present disclosure is located above a first conductive structure 101 and below a second conductive structure 102, where the through-hole contact portion 100 is configured to electrically connect the first conductive structure 101 with the second conductive structure 102. The first conductive structure 101 and the second conductive structure 102 may be, for example, additional through-hole contact portions, conductive layers (such as metal layers, transparent conductive layers, etc.), metal electrodes, etc. The through-hole contact portion 100 includes: a through-hole 108, filling metal 105, a first metal barrier layer 106, a second metal barrier layer 104, and a passivation layer 107. These components are described in detail below, respectively. It is noted that in different embodiments, certain components such as the passivation layer 107 and the second metal barrier layer 104 are optional according to the need.

The through-hole 108, which are formed in the insulating layer 103 and have hollow cavity. The through-hole 108 is an important component used to connect different layers of metal or semiconductor structures, when conductive metal is deposited in the cavity of the through-hole 108, then it is called a through-hole contact portion 100. The formation method of through-hole includes, for example, the following types:

Photolithography and Etching: First, photoresist is coated on the surface to be perforated, and then photolithography technology is used to transfer the desired through-hole pattern onto the photoresist. Next, the uncovered portion of the photoresist is removed through an etching process to form through holes on the semiconductor surface.

Laser drilling: A laser beam is used to drill holes in the surface to be perforated (herein is the insulating layer 103) to form the through-hole.

Chemical vapor deposition (CVD): A layer of material is deposited on the surface to be perforated using the CVD method, this material is then removed through etching or other methods to form the through-hole.

Ion implantation: Ions are implanted into the material to be perforated to change its electrical properties. The ion implantation area is then removed through etching or other methods to form the through-hole.

Reactive ion etching (RIE): Using the principles of chemical reactions and ion bombardment, through-hole is etched on the surface to be perforated. RIE can achieve high-resolution and high-precision etching.

Deep reactive ion etching (DRIE): DRIE is a technique specifically used for etching high aspect ratio structures. It can etch deep and narrow through holes in the material to be perforated.

The diameter of the through-hole 108 may be, for example, 0.2 to 1 μm, and the height may be, for example, 2 to 5 μm.

Filling metal 105, which is arranged in the hollow cavity of the through-hole 108 for conducting electricity. The material of the filling metal 105 is, for example, a metal with good conductivity, such as copper, gold, silver, and tin, etc. The filling metal 105 may, for example, at least partially fill the through-hole 108, preferably completely filling the through-hole 108. In the case of partially filling the through-hole 108, the filling metal 105 must ensure that the first conductive structure 101 and the second conductive structure 102 are electrically connected with each other.

The first metal barrier layer 106, which is arranged between the bottom of the through-hole 108 and the first conductive structure 101 to block diffusion of the filling metal 105 and prevent oxidation of the first conductive structure 101 when exposed to air. Herein, the area of the first metal barrier layer 106 is greater than the bottom area of the through-hole 108, so that even if the original alignment position of the through-hole 108 and the first conductive structure 101 is offset by a certain distance, the first metal barrier layer 106 can still completely cover the bottom of the through-hole 108, so that the diffusion or oxidation of the filling metal 105 at the bottom of the through-hole is better prevented. For example, the cross-sectional length of the first metal barrier layer 106 is X micrometers larger than the bottom diameter of the through-hole 108, or 10% to 50% larger, where X is 0.5 to 1 μm, and the first metal barrier layer 106 is centrally arranged at the alignment position of the through-hole 108 with first conductive structure 101, which allows the through-hole 108 to shift laterally by X/2 micrometers relative to the alignment position, and the first metal barrier layer 106 still can completely cover the bottom of the through-hole 108 to prevent diffusion or oxidation of filling metal 105.

The first metal barrier layer 106 may, for example, include a layered structure, such as a first metal layer and a second metal layer. The first metal layer includes a plurality of stacked layers of titanium layer and platinum layer, where the titanium layer and platinum layer are arranged alternately with each other. The number of the stacked layers is 1 to 5, preferably 3. The thickness of the titanium layer is 100 to 300 angstroms, preferably 200 angstroms. The thickness of the platinum layer is 100 to 300 angstroms, preferably 200 angstroms. The second metal layer is made of titanium. The thickness of the second metal layer is 200 to 400 angstroms, preferably 300 angstroms. 1 angstrom = 1 × 10⁻¹⁰ meters. The present disclosure improves the material and structure of the metal barrier layer by using combinations of multiple titanium-platinum stacked layers plus a titanium layer, and metal diffusion in the through-hole contact portion can be better prevented. The ratio of the cross-sectional length of the first metal barrier layer 106 to the diameters of the through-hole 108 may be, for example, 1.2 to 1.8. Furthermore, the offset between the centerlines of the through-hole 108 and the centerline of the first conductive structure 101 may be, for example, 0.1 to 0.3 μm, where as long as the cross-sectional length of the first metal barrier layer 106 is greater than the diameter of the through-hole 108 by more than the offset, the offset will not cause diffusion of the filling metal in the through-hole 108, but it will still be completely blocked by the first metal barrier layer 106.

The second metal barrier layer 104, which is arranged between the inner walls of the through-hole 108 and the filling metal 105 to block diffusion of the filling metal 105, for example, it prevents the filling metal 105 from diffusing into the insulating layer 103. The second metal barrier layer 104 may have the same material and structure as the first metal barrier layer 106, but may also have other materials and structures, such as tantalum (Ta) and tantalum nitride (TaN) (which can block copper atom diffusion), titanium (Ti) and titanium nitride (TiN), etc.

The passivation layer 107, which is arranged between the through-hole 108 and the first conductive structure 101 and/or the second conductive structure 102 and exposes the first metal barrier layer 106. The passivation layer 107 serves to prevent the interfacial oxidation of first conductive structure 101 during the formation of the through-hole contact portion 100. The breakdown field strength of the passivation layer is not less than 1×107 V/cm, or the breakdown field strength of the passivation layer is not less than 6×108 V/cm. Materials of the passivation layer 107 may include, for example, silicon nitride, aluminum oxide, silicon dioxide, and combinations of silicon nitride and aluminum oxide, or other combinations of the aforementioned components. The formation method of the passivation layer 107 is, after cleaning the interface of the first conductive structure 101 with hydrochloric acid, a passivation layer 107 (such as silicon nitride or aluminum oxide layer) is coated on the interface, and then a part of the passivation layer 107 is etched to expose the position where the first conductive structure 101 needs to be electrically connected with the through-hole contact portion 100, and a first metal barrier layer 106 is deposited in this part. The area of the etched part preferably may be larger than the bottom area of the through-hole 108, so that a first metal barrier layer 106 larger than the bottom area can be deposited. Furthermore, the deposition range of the passivation layer 107 may be within a certain radius area around the through-hole deposition position, and the radius is, for example, 1 to 5 μm.

As can be seen from the above, the present disclosure can substantially prevent metal diffusion from the through-hole contact portion 100 into the first conductive structure 101 (e.g., the drive circuit or metal layer of the LED) by arranging the first metal barrier layer 106 between the bottom of the through-hole contact portion 100 and the first conductive structure 101 electrically connected with it. Moreover, by appropriately enlarging the first metal barrier layer 106 in design, for example, enlarging it to greater than the bottom area of the through-hole, even if the through-hole contact portion 100 deviates from the alignment position on the first conductive structure, the metal barrier effect can still be achieved.

FIG. 2 illustrates a schematic diagram of a second embodiment of the through-hole contact portion 100 for a micro-LED according to the present disclosure.

The second embodiment in FIG. 2 is substantially the same as the first embodiment in FIG. 1, and the primary difference lies in that, in the second embodiment, both the first metal barrier layer 106 and the passivation layer 107 are arranged between the top of the through-hole 100 and the second conductive structure 102. Herein, the material and structure of the first metal barrier layer 106 may be the same as those of the first metal barrier layer 106 in the first embodiment. Herein, the function of the first metal barrier layer 106 is to prevent the filling metal 105 in the through-hole contact portion 100 from diffusing into the second conductive structure 102. In the case of a micro-LED, the second conductive structure 102 may be the light-emitting mesa of the micro-LED. Herein, the function of the passivation layer 107 is to prevent the top filling metal of the through-hole contact portion 100 from being oxidized during the formation of the electrical connection between the second conductive structure 102 and the through-hole contact portion 100. Herein, the passivation layer 102 also has a notch to expose the first metal barrier layer 106. The formation method of the first metal barrier layer 106 is, for example, as follows: first, the top surfaces of the insulating layer and the through-hole contact portion 100 are cleaned using a cleaning agent such as hydrochloric acid, etc.; then, a passivation layer is formed thereon; next, the passivation layer is etched to expose at least a part of the top surface of the through-hole contact portion 100, preferably, the entire through-hole contact portion 100 and a part of the insulating layer 103; then, the first metal barrier layer 106 is formed on the etched passivation layer; finally, the second conductive structure 102 is formed on the first metal barrier layer 106.

As can be seen from the above, the present disclosure can substantially prevent metal diffusion from the through-hole contact portion 100 into the second conductive structure 102 (e.g., the light-emitting mesa of the LED) by arranging the first metal barrier layer 106 between the top of the through-hole contact portion 100 and the second conductive structure 101 electrically connected with it. Moreover, by appropriately enlarging the first metal barrier layer 106 in design, for example, enlarging it to greater than the bottom area of the through-hole, even if the through-hole contact portion 100 deviates from the alignment position on the second conductive structure, the metal barrier effect can still be achieved.

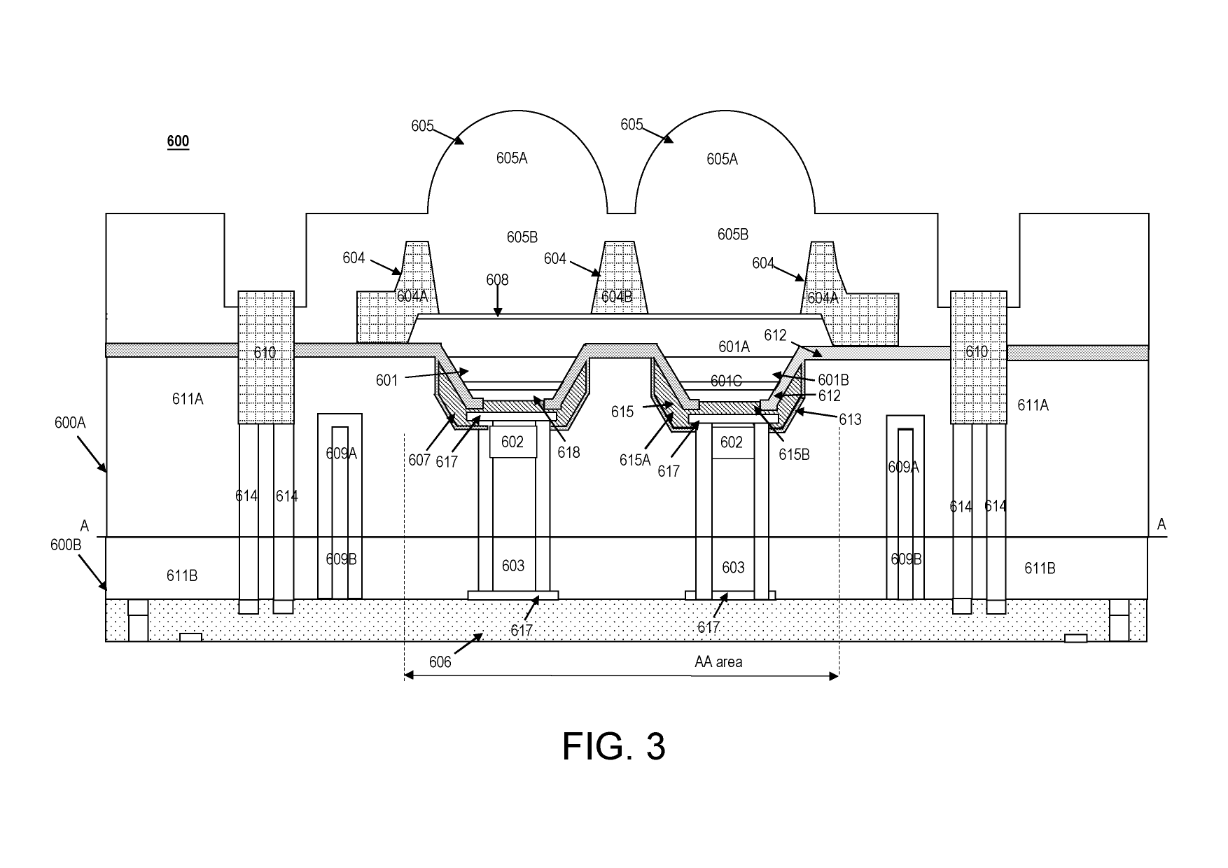

FIG. 3 illustrates a schematic diagram of a third embodiment of the through-hole contact portion 100 for a micro-LED according to the present disclosure.

As shown in FIG. 3, in the third embodiment, the through-hole contact portion 602 according to the present disclosure is applied to a micro-LED chip 600, specifically, the first through-hole contact portion 602 and the second through-hole contact portion 603 according to the present disclosure are used to electrically connect the epitaxial layer 601 (or light-emitting mesa) and the drive circuit 606, and metal diffusion from the first and second through-hole contact portions 602 and 603 into the epitaxial layer 601 and the drive circuit 606 can be prevented, and the oxidation of the metal can be prevented. The micro-LED chip 600 using the first and second through-hole contact portions 602 and 603 according to the present disclosure are described in detail below

As shown in FIG. 3, the micro-LED chip 600 according to the present disclosure includes an upper stacked layer 600A and a lower stacked layer 600B, where the upper stacked layer 600A and the lower stacked layer 600B are formed into a complete micro-LED chip 600 through hybrid bonding at interface A. The structure and components of the upper stacked layer 600A and the lower stacked layer 600B are described in detail below.

### Upper stacked layer

The upper stacked layer 600A includes a first insulating layer 611A, a light-emitting mesa 601, a transparent conductive layer 608, a first electrode 604 (cathode), a first through-hole contact portion 602, a second electrode 610 (anode), a first bonding mark 609A, and microlens 605. The various components are described below, respectively.

The first insulating layer 611A is configured to accommodate at least a part of the light-emitting mesa 601 and provide electrical insulation for it. Herein, the first insulating layer 611A has a recess 607 configured to accommodate the light-emitting layer and the second epitaxial layer of the light-emitting mesa 601, as well as the ancillary structures. For a detailed description of the light-emitting mesa 601 and its ancillary structures (such as the passivation layer 612, the reflective mirror layer 615, etc.), reference may be made to the light-emitting mesa 601 and description thereof. Herein, it should be noted that the recess 607 may be formed after the light-emitting mesa 601, i.e., the light-emitting mesa 601 and its ancillary structures are first formed on a temporary substrate, then the first insulating layer 611A surrounding them is formed on the light-emitting mesa and its ancillary structures. The material of the first insulating layer 611A may be, for example, silicon dioxide, silicon nitride, high-k dielectric materials (such as hafnium oxide, aluminum oxide, etc.), and so on. Methods for forming the first insulating layer 611A may include thermal oxidation, chemical vapor deposition (CVD), etc. The thickness of the first insulating layer 611A is, for example, 1 to 3 μm, preferably 2 μm, and more preferably 0.6 to 1.4 μm. Furthermore, the first insulating layer 611A may be planarized at interface A (e.g., through chemical mechanical polishing CMP) to facilitate hybrid bonding with the second insulating layer 611B.

The first insulating layer 611A is transparent to light emitted from the light-emitting mesa 601. In some embodiments, the first insulating layer 611A is made of a dielectric material such as solid inorganic material or plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. In some embodiments, the first insulating layer 611A may facilitate the passage of light emitted from the light-emitting mesa 601. In some embodiments, the first insulating layer 611A may include a plurality of portions, such as three embedded dielectric portions and two adhering dielectric portions. The embedded dielectric portions refer to the dielectric layers surrounding each light emitting diode structure; while the adhering dielectric portions refer to the dielectric layers between two light emitting diode structures. The embedded dielectric portions and the adhering dielectric portions may have the same or different compositions.

The light-emitting mesa 601 is configured to emit light, where the top surface area of the light-emitting mesa 601 is greater than the bottom surface area of the light-emitting mesa 601. The inclination angle of the light-emitting mesa 601 may be, for example, 10° to 85°, preferably 30° to 70°, and particularly 35° to 50°. The light-emitting mesa 601 includes a first epitaxial layer 601A, a light-emitting layer 601B, and a second epitaxial layer 601C, where the first epitaxial layer 601A is arranged on the top of the light-emitting mesa, i.e., the side facing the light extraction surface; the light-emitting layer 601B is arranged in the recess 607 and arranged between the first epitaxial layer 601A and the second epitaxial layer 601C; and the second epitaxial layer 601C is arranged on the bottom of the light-emitting mesa 601, i.e., the side facing the drive circuit 606. The light-emitting layer 601B may include, for example, a multi-quantum-well layer and an electron barrier layer. In one embodiment of the present disclosure, the first epitaxial layer 601A is an N-type GaN layer or an N-type AlGaN layer, and the second epitaxial layer 601C is a P-type GaN layer or a P-type AlGaN layer, i.e., the material of the second epitaxial layer is a material layer of a second conductivity type including at least two or more elements of Ga, N, As, Al, In, and P, and the first epitaxial layer is a material layer of a first conductivity type including at least two or more elements of Ga, N, As, Al, In, and P. The multi-quantum-well layer is an InGaN/GaN multi-quantum-well layer, an InGaN/AlGaN multi-quantum-well layer, or an InGaAs/AlGaAs multi-quantum-well layer. The electron barrier layer is arranged on the first side of the light-emitting layer, and the first side refers to the side along which electrons migrate out of the light-emitting layer. In yet another embodiment of the present disclosure, the first epitaxial layer may also be a P-type GaN layer or a P-type AlGaN layer, and the second epitaxial layer is an N-type GaN layer or an N-type AlGaN layer. The top width of the light-emitting mesa 601 is, for example, 0.5 to 3 μm, preferably 1.0 to 2.0 μm. The thickness of the first epitaxial layer 601A is, for example, 4000 to 5000 angstroms, the thickness of the light-emitting layer 601B is, for example, 3500 to 4000 angstroms, and the thickness of the second epitaxial layer 601C is, for example, 2500 to 3500 angstroms. 1 angstrom = 10⁻¹⁰ meters. From FIG. 3, it can also be seen that the first epitaxial layer 601A is located outside the recess 607, while the light-emitting layer 601B and the second epitaxial layer 601C are located within the recess 607, therefore, the surface area of the first epitaxial layer 601A is not limited by the aperture area of the recess 607 but can be significantly greater than the aperture area of the recess 607, thereby significantly increasing the area and thickness of the first epitaxial layer 601A; furthermore, due to the fact that merely the light-emitting layer 601B and the second epitaxial layer 601C need to be accommodated in the recess 607, these two layers have a larger area and thickness compared to the structure that requires accommodating three layers in the prior art, and thus the area and thickness of the epitaxial layer 601 are better increased, and the light output is improved. It can also be seen herein that the first epitaxial layer 601A passes through the first electrode 604 (herein is the cathode) from below the first electrode 604, so that the first epitaxial layers 601A of adjacent light-emitting mesas 601 can be connected to each other, and thus in the case of a common-cathode structure (i.e., where the first epitaxial layers of all micro-LEDs in the same array are connected to a common cathode), compared to the case where it is connected to the cathode 604 solely by the transparent conductive layer 608 covering it, the conductivity between the cathode 604 and the first epitaxial layer 601A can be significantly enhanced, thereby increasing its power supply. Furthermore, the contact cross-section between the first epitaxial layer 601A and the cathode 604 at the edge is partially planar and partially inclined surface. The inclined surface increases the contact area between the first epitaxial layer 601A and the cathode 604 compared to a vertical surface, and thus the conductivity is increased.

In one embodiment of the present disclosure, the first epitaxial layer (or the first type epitaxial layer) is a semiconductor material with a first conductivity type and includes a plurality of semiconductor layers. The main matrix material may be, but is not limited to, materials such as Ga, N, As, P, In, or Al, etc. Furthermore, the first epitaxial layer may include, from top to bottom, but is not limited to, a waveguide layer, a confinement layer, a transition layer, and a window layer; furthermore, an ohmic contact layer may be formed below the window layer. In some embodiments, the second epitaxial layer (or simply referred to as the second type epitaxial layer) is a semiconductor material with a second conductivity type and includes a plurality of semiconductor layers. The main matrix material of the second epitaxial layer may be, but is not limited to, two or more materials such as Ga, N, As, P, In, or Al. Furthermore, the second epitaxial layer may include, from top to bottom, but is not limited to, a confinement layer and a waveguide layer; furthermore, in some embodiments, an ohmic contact layer may be formed on the confinement layer. In one embodiment of the present disclosure, the first epitaxial layer is an N-type GaN layer or an N-type AlGaN layer, and the second epitaxial layer is a P-type GaN layer or a P-type AlGaN layer, i.e. the material of the second epitaxial layer is a material layer of a second conductivity type including at least two or more elements of Ga, N, As, Al, In, and P, and the first epitaxial layer is a material layer of a first conductivity type including at least two or more elements of Ga, N, As, Al, In, and P. In another embodiment of the present disclosure, the first epitaxial layer may also be a P-type GaN layer or a P-type AlGaN layer, and the second epitaxial layer is an N-type GaN layer or an N-type AlGaN layer. In an embodiment of the present disclosure, the light-emitting mesa is step-shaped or trapezoidal.

The light-emitting mesa 601 also includes ancillary structures such as passivation layers 612 and 613, a reflective mirror layer 615, etc. The passivation layer 612 is arranged between the light-emitting mesa 601 and the reflective mirror layer 615, and optionally extends on the upper surface of the first insulating layer 611A, and the passivation layer 613 is arranged between the inner wall of the recess 607 and the reflective mirror layer 615, and optionally extends on the upper surface of the first insulating layer 611A. In another embodiment, merely one of the passivation layers 612 and 613 extends on the upper surface of the first insulating layer 611A, or neither does not extend over the upper surface of the first insulating layer 611A, instead, they extend merely until the upper surface of the first insulating layer 611A, while the upper surface of the first insulating layer 611A is covered by another insulating layer or dielectric layer. The function of passivation layers 612 and 613 is not only to reduce current leakage at the sidewalls, but also to passivate sidewall defects and block damage to the light-emitting mesa caused by water, oxygen, etc., during operation, they can also prevent metal diffusion from the reflective mirror layer 615, the cathode 104 etc. to the first insulating layer 611 or the light-emitting mesa 601. The passivation layers 612 and 613 may be formed by depositing SiO2 material using a CVD process, and also may be formed by depositing Al2O3 material using an ALD process. The reflective mirror layer 615 is configured to reflect light from the light-emitting mesa 601 upward. For this purpose, the reflective mirror layer 615 has an inclined surface on the side facing the light-emitting mesa 601. The material of the reflective mirror layer 615 is, for example, silver, or a combination of a plurality of metal layers such as nickel, silver, platinum, etc., and its thickness is 2000 to 4000 angstroms, preferably 3000 to 3500 angstroms. The reflective mirror layer 615 can be formed, for example, by methods such as evaporation, sputtering, or chemical vapor deposition (CVD), etc. The thickness of the passivation layer 612 between the reflective mirror layer 612 and the light-emitting mesa 601 is 800 to 2000 angstroms, preferably 1000 to 1600 angstroms. The thickness of the passivation layer 613 between the reflective mirror layer 615 and the inner wall 607 of the recess is 200 to 800 angstroms, preferably 300 to 600 angstroms.

The transparent conductive layer 608 is arranged on the first epitaxial layer 601A and electrically connects the first electrode 604 (cathode) with the first epitaxial layer 601A. Herein, the transparent conductive layer 608 extends on the first epitaxial layer 601A and fully covers the first epitaxial layer 601A, thereby providing more uniform power supply for the first epitaxial layer 601A. In other embodiments, the transparent conductive layer 608 may merely partially cover the first epitaxial layer 601A. Furthermore, the transparent conductive layer 608 extends below the first electrode 604, which is the cathode in this case, such that the transparent conductive layer 608 extends continuously on the first epitaxial layer 601A of adjacent light-emitting mesas 601A, so that the coverage area for the first epitaxial layer 601A is increased. The material of the transparent conductive layer 608 is, for example, metal oxide such as indium tin oxide ITO or zinc oxide ZnO, etc., and its formation methods, for example, include physical vapor deposition (PVD), chemical vapor deposition (CVD), sol-gel method, solution coating method, etc.

The first electrode 604, herein is the cathode, and is arranged to surround the light-emitting mesa 601. The cathode 604 and its connecting components may be made of materials such as metals (such as silver, gold, or platinum), graphene, ITO, aluminum doped zinc oxide (AZO) or fluorine doped tin oxide (FTO), or any combination of the above materials. In yet another embodiment of the present disclosure, the cathode 604 and its connecting components may be made of non-transparent or transparent conductive materials, such as indium tin oxide (ITO). In a preferred embodiment, the cathode 604 is made of a reflective metal (such as copper, silver or aluminum), so that the cathode 604 can optically isolate adjacent light-emitting mesas 601 from each other and meanwhile also can reflect light from the light-emitting mesas 601, for example, reflect the light upward to the microlens 605, thereby increasing light output. In another embodiment, a reflective layer, such as a silver layer, may be coated onto the surface of the cathode 604 to provide reflective capability. Herein, the surface of the cathode 604 facing the light-emitting mesa 601A is an inclined surface, and it is inclined toward two sides (i.e. inclined from the bottom surface toward two sides), so that the light falling on it can be reflected upward, i.e. toward the light extraction side. Furthermore, the cathode 604 may be divided into an edge cathode 604A and a central cathode 604B, where the edge cathode 604A is arranged between the second electrode 610 (herein is the anode) and the outermost light-emitting mesa 601, where a part of the edge cathode 604A is arranged on the passivation layer 612, and another part is arranged on the transparent conductive layer 608, while the central cathode 604B is arranged between adjacent light-emitting mesas 601, where the central cathode 604B is arranged on the transparent conductive layer 608. In this way, the edge cathode 604A can completely cover the side surface of the first epitaxial layer 601A and be in electrical contact with it, thereby increasing the electrical contact area between the cathode 604 and the first epitaxial layer 601A.

The first through-hole contact portion 602 is electrically connected with the bottom of the light-emitting mesa 601 and passes through the first insulating layer 611A. The first through-hole contact portion 602 is used for hybrid bonding with the second through-hole contact portion 603, and thus electrically connects the bottom of the light-emitting mesa 601, particularly the second epitaxial layer 601C to the second electrode 610 (herein it is the anode). The first through-hole contact portion 602 is preferably a cylindrical through-hole, and the inner wall and/or central space is filled with a conductor, such as metal copper. The diameter of the first through-hole contact portion 602 is of 0.3 to 2 μm, preferably 0.6 to 1.4 μm. The first through-hole contact portion 602 may be planarized at interface A (e.g., through chemical mechanical polishing CMP) to facilitate hybrid bonding with the second through-hole contact portion 603. Furthermore, in order to enhance the bonding strength and improve the conductivity between the first through-hole contact portion 602 and the second through-hole contact portion 603, a first interface metal layer may be arranged at the first aperture of the first through-hole contact portion 602, and the area of the first interface metal layer is greater than the area of the first aperture 203. Similarly, a second interface metal layer may be arranged at the second aperture of the second through-hole contact portion 603, and the area of the second interface metal layer is greater than the area of the second aperture. The areas of the first interface metal layer and the second interface metal layer may be equal, or the area of the first interface metal layer may be greater or less than the area of the second interface metal layer. After the first interface metal layer and the second interface metal layer are bonded to each other, the formed bonding surface is greater than the bonding surface formed by directly bonding the first aperture of the first through-hole contact portion 602 and the second aperture of the second through-hole contact portion 603, and thus the bonding strength is enhanced and the conductivity between the first through-hole contact portion 602 and the second through-hole contact portion 603 is improved. The first interface metal layer and the second interface metal layer 202 are made of, for example, a conductive metal such as copper. Their formation methods may include, for example, physical vapor deposition (PVD), chemical vapor deposition (CVD), electroplating, chemical plating, and so on. The formation method of the first through-hole contact portion 602 may be, for example, as follows: a light-emitting mesa 601 and a first insulating layer 611A are formed on a temporary substrate, then the first insulating layer 611A is etched to form a through-hole leading to the bottom of the light-emitting mesa 601, subsequently, a metal is deposited in the through-hole, and finally the aperture of the through-hole is planarized to form the bonding surface.

Furthermore, the first through-hole contact portion 602 is constructed according to the present disclosure, where the first through-hole contact portion 602 is used to electrically connect the drive circuit 606 with the bottom (herein is the reflective mirror layer 607) of the epitaxial layer 601 (or light-emitting mesa) of the micro-LED array after bonding with the second through-hole contact portion 603, thereby connecting the epitaxial layer 601 to the anode 610. Herein, a first metal barrier layer 617 is arranged between the through-hole contact portion 602 and the reflective mirror layer 607. The first metal barrier layer 617 can prevent the metal in the first through-hole contact portion 602 from diffusing into the epitaxial layer 601 or the insulating layer 611A through the reflective mirror layer 607 and other layers (e.g., the bottom transparent electrode layer) that may be arranged therebetween, or from oxidizing. If the metal in the first through-hole contact portion 602 diffuses into the epitaxial layer 601, then the luminous performance of the epitaxial layer 601 will be affected; if it diffuses into the insulating layer 611A, then the insulating effect of the insulating layer 611A will be affected, thereby leading to leakage current or even short circuits; if the metal in the first through-hole contact portion 602 oxidizes, then it may cause poor contact between the first through-hole contact portion 602 and the reflective mirror layer 607, or even result in an open circuit in the electrical lines to the epitaxial layer 601. From this, it can be seen that by arranging the first through-hole contact portion 602 according to the present disclosure, metal diffusion in the first through-hole contact portion 602 can be effectively avoided, and thus risks such as reduced luminous performance, short circuit, and open circuit, etc. of the micro-LED can be effectively prevented.

The second electrode 610, herein is the anode, and is electrically connected with the drive circuit 606 through a third through-hole contact portion 614 passing through the first insulation layer 611A and the second insulation layer 611B. The anode 610 may be, for example, connected to an external power source or control source for supplying power for the micro-LED chip 600 or controlling the micro-LED chip 600. Herein, the third through-hole contact portion 614 may include a plurality of through-hole contact portions for connecting the second epitaxial layers 601C of a plurality of light-emitting mesas to the anode 610. Herein, it is exemplarily shown that the third through-hole contact portion 614 includes two through-hole contact portions, but this is merely an example, and other numbers of through-hole contact portions 614 are also conceivable. The third through-hole contact portion 614 may be formed either before hybrid bonding or after hybrid bonding. If the third through-hole contact portion 614 is formed before hybrid bonding, then the upper and lower portions of the third through-hole contact portion 614 are first formed in the upper stacked layer 600A and the lower stacked layer 600B, respectively, then after hybrid bonding, these two portions are interconnected to form the third through-hole contact portion, and then the first insulating layer 611A is etched from above to form the anode 610 on the third through-hole contact portion 614. If the third through-hole contact portion 614 is formed after hybrid bonding, then the first insulating layer 611A is etched from above to form a through-hole leading to the drive circuit 606, metal is then deposited in the through-hole, then the third through-hole contact portion 614 is etched to form a recess, metal is then deposited in the recess to form the anode 610. The anode 610 and its connecting components may be made of materials such as metals (e.g., copper, silver, or aluminum), graphene, ITO, aluminum doped zinc oxide (AZO), or fluorine doped tin oxide (FTO), or any combination of the above materials.

The first bonding mark 609A is arranged in the first insulating layer 611A and exposes the first marking surface, i.e., the aperture of the first bonding mark. The function of the first bonding mark 609A in the upper stacked layer 600A is to serve as a mark aligned with the second bonding mark 609B in the lower stacked layer 600B, and thus precise hybrid bonding is achieved, where the second bonding mark 609B is arranged in the second insulating layer 600B and exposes the second marking surface, i.e., the aperture of the second bonding mark. The alignment method of the first bonding mark 609A with the second bonding mark 609B is to align and adhere the first marking surface with the second marking surface during hybrid bonding, at this time, the upper stacked layer 600A and the lower stacked layer 600B have been aligned, and then hybrid bonding can be performed. The first bonding mark 609A and the second bonding mark 609B may be metal through-holes, and the two may be bonded at the interface. Furthermore, the first bonding mark 609A and the second bonding mark 609B may have enlarged apertures and/or the apertures may be coated with a metal layer to facilitate identification of their positions and enhance bonding strength.

The microlens 605 is arranged above the light-emitting mesa 601 for shaping such as focusing or collimating the light emitted therefrom. The microlens includes a lens portion 605A and a spacer portion 605B. The lens portion 605A is arranged at the outermost side, i.e., the topmost and configured to shape light from the light-emitting mesa 601. The spacer portion 605B is arranged between the lens portion 605A and the light-emitting mesa 601 to adjust the focal position of the lens portion 605A, for example, parameters such as the thickness of the spacer portion 605B and the curvature of the lens portion 605A, etc. are adjusted, such that the focal point of the lens portion 605A is precisely located in the light-emitting mesa 601 of the micro-LED. The width of the microlens 605 is, for example, 0.8 to 4 μm, preferably 1 to 3 μm. The distance between the lens portion 605A and the cathode 604 is, for example, 0.05 to 4 μm, preferably 0.1 to 0.3 μm. The microlens 605 corresponds one-to-one with the light-emitting mesa 601. Meanwhile, in the present embodiment, adjacent microlenses 605 have gaps between them and their bottoms are connected with each other. The bottoms of the gaps are higher than the top of the light-emitting mesa 601 or higher than the bottom of the light-emitting layer 601B of the light-emitting mesa 601, and the lens portion 604A is located above the cathode 604. The microlens 605 may be formed through a plurality of deposition steps, and during the formation process of the microlens, a SiO2 film layer is first deposited, then ion etching is performed, and the microlens is formed at positions on the surface of the transparent conductive layer 608 corresponding to each light-emitting mesa 601.

The microlens may be made of various materials transparent at the wavelength emitted by a single micro-LED pixel. Examples of transparent materials used for the microlens include polymers, dielectrics, and semiconductors. In some embodiments, dielectric materials include one or more materials such as silicon oxide, silicon nitride, silicon carbide, titanium oxide, zirconium oxide, aluminum oxide, etc. In some embodiments, the microlens 260 is made of photoresist. In some embodiments, the shape of the microlens is typically a hemispherical shape. In some embodiments, the central axis of the microlens aligns with or is the same as the central axis of the individual micro-LED pixel without a lens. It should be understood that a complete display panel includes an array of numerous individual pixels and many microlenses. Furthermore, the relationship between the microlens and the pixel light source is not necessarily one-to-one, and the relationship between the drive circuit (not shown) and the pixel light source also is not necessarily one-to-one. The pixel light source may also include a plurality of individual light-emitting elements, such as individual pixel LEDs connected in parallel. In some embodiments, a single microlens may cover a plurality of individual LED pixels without lenses. A single microlens has positive focal power, and its position can reduce the divergence or viewing angle of the light emitted by the corresponding pixel light source. For example, the light beam emitted by the pixel light source originally has a relatively wide divergence angle. In one embodiment, the initial angle of the beam edge rays relative to a vertical axis perpendicular to the substrate is greater than 60°. After being refracted by a microlens, the divergence angle of the new edge rays is now reduced. In one embodiment, the reduced angle is less than 30°. The microlenses in a microlens array are usually the same. Examples of microlenses include spherical microlenses, non-spherical microlenses, Fresnel microlenses, and cylindrical microlenses.

### Lower stacked layer

The lower stacked layer 600B includes a second insulating layer 611B, a second through-hole contact portion 603, a drive backplane 606, and a second bonding mark 609B. The various components are described below, respectively.

The second insulating layer 611B is arranged on the drive backplane 606 and is configured to accommodate the second through-hole contact portion 603. The material of the second insulating layer 611B may be, for example, silicon dioxide, silicon nitride, high-k dielectric materials (e.g., hafnium oxide, aluminum oxide, etc.), and so on. The second insulating layer 611B may be, for example, formed on the drive backplane 606 through methods such as thermal oxidation or chemical vapor deposition (CVD), etc. The thickness of the second insulating layer 611B may be, for example, 1 to 3 μm, preferably 2 μm, and more preferably 0.6 to 1.4 μm. Furthermore, the second insulating layer 611B may be planarized at interface A (e.g., through chemical mechanical polishing CMP) to facilitate hybrid bonding with the first insulating layer 611A.

The second insulating layer 611B is transparent to light emitted from the light-emitting mesa 601. In some embodiments, the second insulating layer 611B is made of a dielectric material such as solid inorganic material or plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. In some embodiments, the second insulating layer 611B may facilitate the passage of light emitted from the light-emitting mesa 601. In some embodiments, the second insulating layer 611B may include a plurality of portions, such as three embedded dielectric portions and two adhering dielectric portions. The embedded dielectric portions refer to the dielectric layers surrounding each light emitting diode structure; while the adhering dielectric portions refer to the dielectric layers between two light emitting diode structures. The embedded dielectric portions and the adhering dielectric portions may have the same or different compositions.

The second through-hole contact portion 603, which passes through the second insulating layer 611B. The second through-hole contact portion 603 is configured to hybrid bond with the first through-hole contact portion 602 at interface A, and thus electrically connect the bottom of the light-emitting mesa 601, particularly the second epitaxial layer 601C to the second electrode 610 (herein it is the anode). The second through-hole contact portion 603 is preferably a cylindrical through-hole, and the inner wall and/or central space is filled with a conductor, such as metallic copper. The diameter of the second through-hole contact portion 603 is of 0.5 to 2.2 μm, preferably 0.8 to 1.6 μm. The second through-hole contact portion 603 may be planarized at interface A (e.g., through chemical mechanical polishing CMP) to facilitate hybrid bonding with the first through-hole contact portion 602. Furthermore, in order to enhance the bonding strength and improve the conductivity between the second through-hole contact portion 603 and the first through-hole contact portion 602, a second interface metal layer may be arranged at the second aperture of the second through-hole contact portion 603, and the area of the second interface metal layer is greater than the area of the second aperture. Similarly, a first interface metal layer may be arranged at the first aperture of the first through-hole contact portion 602, and the area of the first interface metal layer is greater than the area of the first aperture. The areas of the first interface metal layer and the second interface metal layer may be equal, or the area of the first interface metal layer may be greater or less than the area of the second interface metal layer. After the first interface metal layer and the second interface metal layer are bonded to each other, the formed bonding surface is greater than the bonding surface formed by directly bonding the first aperture of the first through-hole contact portion 602 and the second aperture of the second through-hole contact portion 603, and thus the bonding strength is enhanced and the conductivity between the first through-hole contact portion 602 and the second through-hole contact portion 603 is improved. The first interface metal layer and the second interface metal layer are made of, for example, a conductive metal such as copper. Their formation methods may include, for example, physical vapor deposition (PVD), chemical vapor deposition (CVD), electroplating, chemical plating, and so on. The formation method of the second through-hole contact portion 603 may be, for example, as follows: a drive backplane 606 is provided, then a second insulating layer 611B is formed on the drive backplane 606, then the second insulating layer 611B is etched to form through-hole leading to the top of the drive backplane 606, subsequently, a metal is deposited in the through-hole, and finally the aperture of the through-hole is planarized to form the bonding surface.

Furthermore, the second through-hole contact portion 603 is constructed according to the present disclosure, where the second through-hole contact portion 603 is used to electrically connect the drive circuit 606 with the bottom (herein is the reflective mirror layer 607) of the epitaxial layer 601 (or light-emitting mesa) of the micro-LED array after bonding with the first through-hole contact portion 602, thereby connecting the epitaxial layer 601 to the anode 610. Herein, a first metal barrier layer 617 is arranged between the second through-hole contact portion 603 and the drive circuit 606. The first metal barrier layer 617 can prevent the metal in the second through-hole contact portion 603 from diffusing into the drive circuit 606 or the insulating layer 611B, or from oxidizing. If the metal in the second through-hole contact portion 603 diffuses into the drive circuit 606, then the electrical performance of the drive circuit will be affected, such as it causes a short circuit; if it diffuses into the insulating layer 611B, then the insulating effect of the insulating layer 611B will be affected, thereby leading to leakage current or even short circuits; if the metal in the second through-hole contact portion 603 oxidizes, then it may cause poor contact between the second through-hole contact portion 603 and the drive circuit 606, or even result in an open circuit in the electrical lines to the drive circuit 606. From this, it can be seen that by arranging the second through-hole contact portion 603 according to the present disclosure, metal diffusion in the second through-hole contact portion 603 can be effectively avoided, and thus risks such as short circuits or open circuits, etc. in the drive circuit 606 are effectively prevented.

The drive circuit 606 is electrically connected with the second through-hole contact portion 603 to electrically connect the second epitaxial layer 601C of the light-emitting mesa 601 to the anode 610. For this purpose, the drive circuit 606 has conductive line layers for interconnecting each second through-hole contact portion 603 to the corresponding anode 610. The drive circuit 606 may be, for example, a thin-film transistor TFT drive circuit and may include 2T1C drive circuit, 3T1C drive circuit, and 5T2C drive circuit. The drive circuit 606 is configured to drive the micro-LEDs, such as control the switching on/off and brightness of the micro-LEDs. The drive circuit 606 may include, for example, transistors, capacitors, a conductive line layer, an insulating layer, and a metal layer, etc. The conductive line layer is formed on the substrate and configured to supply power to the micro-LED array. The insulating layer is formed on the conductive line layer, where through-hole is arranged in the insulating layer, and through-hole contact portions (e.g., IC copper pillars) are arranged in the through-hole for electrically connecting the conductive line layer with the micro-LED array. The metal layer is used for bonding and electrically contacting the micro-LEDs. The conductive line layer, the metal layer, and the insulating layer may be formed on substrate 601 through deposition methods such as physical vapor deposition (PVD) and chemical vapor deposition (CVD).

In one embodiment of the present disclosure, the drive circuit may be electrically connected with each micro-LED in the micro-LED array through individual metal interconnections. In some embodiments, each micro-LED may be individually electrically controlled by the drive circuit. In some embodiments, the drive circuit may be electrically connected with electrodes of the micro-LED chips through metal interconnections. In some embodiments, a dielectric layer may be formed in the gaps between the micro-LEDs. In some embodiments, the dielectric layer may also be formed in the gaps between the interconnections.

The micro-LED chip includes a plurality of micro-LED arrays, and each micro-LED array includes a plurality of micro-LEDs. The drive method of the micro-LEDs is, for example, a passive matrix (PM) drive, where the cathodes of all micro-LEDs of each array are connected to a cathode together, while micro-LEDs of the same number of each array are connected to corresponding anodes, respectively. Thus, the on/off and brightness of each LED can be individually controlled by controlling the signal on the corresponding cathode and anode.

The second bonding mark 609B is arranged in the second insulating layer 611B and exposes the second marking surface, i.e., the aperture of the second bonding mark. The function of the second bonding mark 609B in the lower stacked layer 600B is to serve as a mark corresponding to the first bonding mark 609A in the upper stacked layer 600A, and thus precise hybrid bonding is achieved. The alignment method of the first bonding mark 609A with the second bonding mark 609B is to align and adhere the first marking surface with the second marking surface during hybrid bonding, at this time, the upper stacked layer 600A and the lower stacked layer 600B have been aligned, and then hybrid bonding can be performed. The first bonding mark 609A and the second bonding mark 609B may be metal through-holes, and the two may be bonded at the interface. Furthermore, the first bonding mark 609A and the second bonding mark 609B may have enlarged apertures and/or the apertures may be coated with a metal layer to facilitate identification of their positions and enhance bonding strength.

After the formation of the lower stacked layer 600A and the upper stacked layer 600B, the lower stacked layer 600A is joined with the upper stacked layer 600B through hybrid bonding, such that the first through-hole contact portion 602 is bonded with the second through-hole contact portion 603 and the first insulating layer 611A is bonded with the second insulating layer 611B, optionally the first bonding mark 609A is bonded with the second bonding mark 609B, and the upper and lower portions of the third through-hole contact portion 614 are bonded with each other. The present disclosure solves the technical problem encountered in manufacturing upside-down arranged trapezoidal light-emitting mesa with a large upper surface and a small lower surface, i.e., the problem of electrical connection of the light-emitting mesa to the driving circuit, by respectively fabricating the upper stacked layer 600A and the lower stacked layer 600B and then joining them with each other through hybrid bonding. The present disclosure achieves electrical connection of the light-emitting mesa 601 to the drive circuit 606 through hybrid bonding, allowing both the upper stacked layer 600A and the lower stacked layer 600B to be manufactured from the surface opposed to the hybrid bonding surface, i.e., interface A, towards the hybrid bonding surface, so that high-quality conductive structures, such as the first to third through-hole contact portions (such as IC copper pillars) are achieved, and the length of the conductive structure can also be flexibly selected.

### An exemplary of the hybrid bonding may include the following two parts

(1) Dielectric-to-dielectric bonding (i.e., bonding between the first insulating layer 611A and the second insulating layer 611B): at room temperature, extremely flat and smooth dielectric surfaces obtained through chemical mechanical polishing (CMP) are brought into close contact at room temperature after activation through methods such as plasma treatment to achieve preliminary bonding.

(2) Metal-to-metal bonding (i.e., bonding between through-hole contact portions): after completing the dielectric-to-dielectric bonding, the upper and lower stacked layers are heated to 200-400°C for annealing treatment to strengthen the dielectric bonding and facilitate metal-to-metal bonding, thereby achieving hybrid bonding.

A plurality of micro-LEDs constitute a micro-LED array, and a plurality of micro-LED arrays constitute a micro-LED chip. The size of each micro-LED chip does not exceed 1 centimeter, preferably not exceeding 20 micrometers. The micro-LED structures are formed in the form of an array in the micro-LED chip, achieving print resolutions such as 1200 DPI, 600 DPI, and resolutions such as 720*480, 640*480, 1920*1080, 1280*720, 2K, or 4K. The diameters of the micro-LED structures are in the nanometer-level, for example, 20 nm to 100 nm, etc.

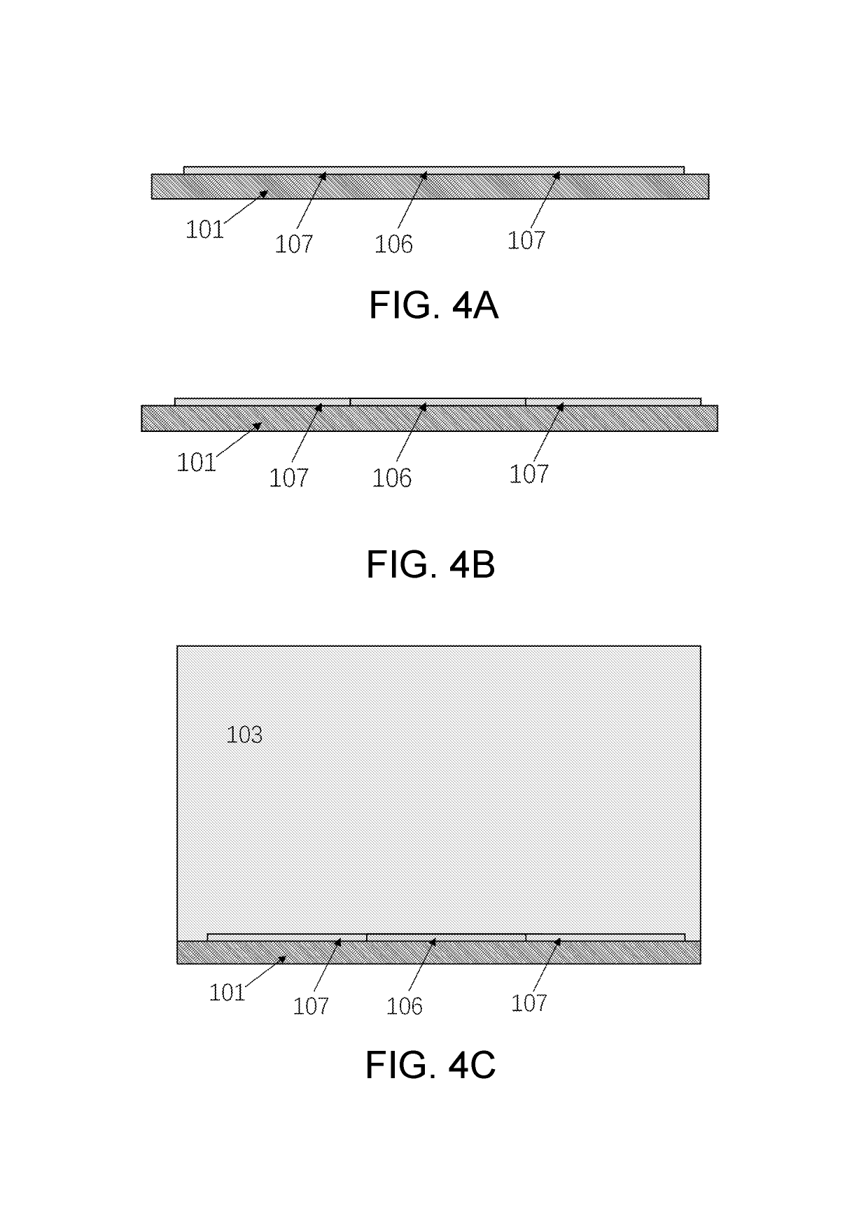

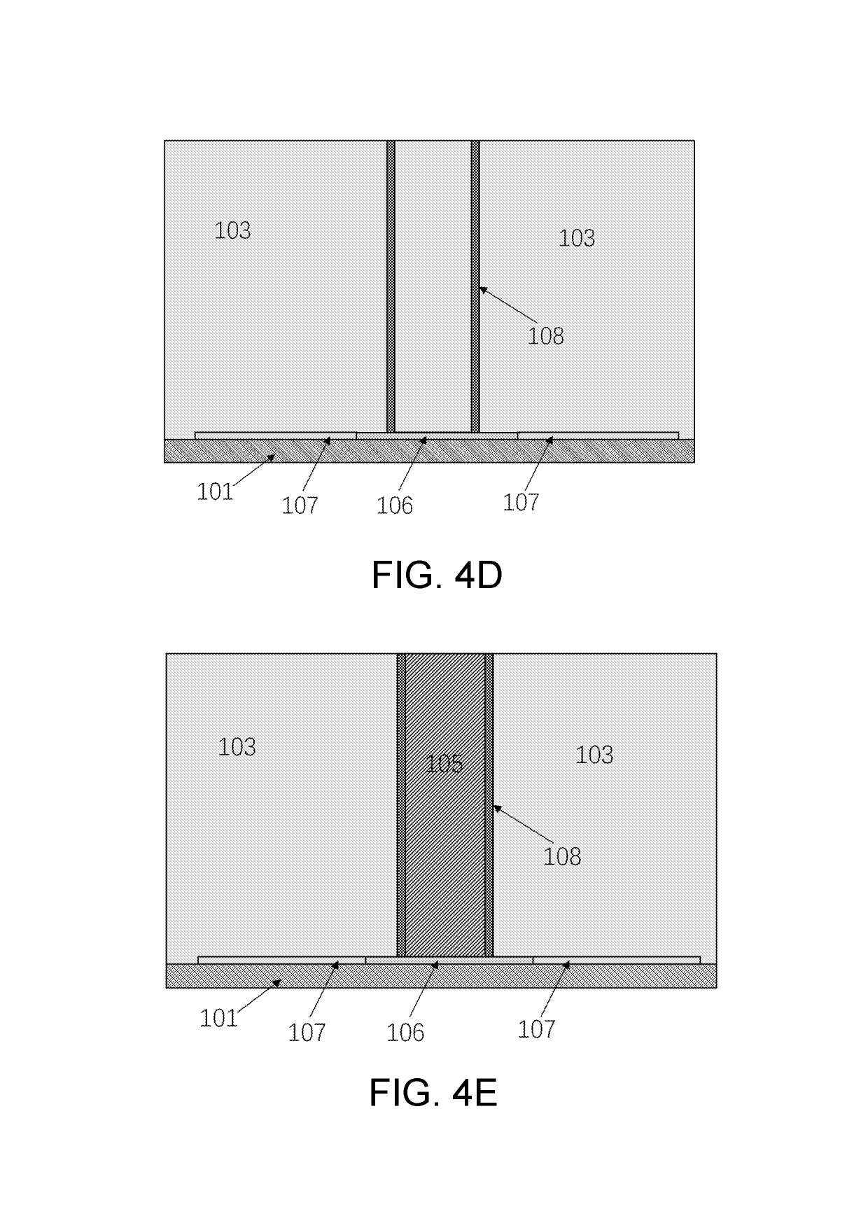

FIGS. 4A-4E illustrate a first embodiment of a method for forming a through-hole contact portion according to the present disclosure.

As shown in FIG. 4A, in step S1, a first conductive structure 101 is provided. The first conductive structure 101 may, for example, be another through-hole contact portion, a conductive layer (such as a metal layer, a transparent conductive layer, etc.), a metal electrode, or the like.

In step S2, a passivation layer 107 is formed on the first conductive structure 101. Methods for forming the passivation layer 107 include, for example: thermal oxidation, chemical vapor deposition (CVD), physical vapor deposition (PVD), atomic layer deposition (ALD), etc.

As shown in FIG. 4B, in step S2, a part of the passivation layer 107 is removed to expose the first conductive structure 101. The removal step may include, for example, photolithography, wet etching, and dry etching, where dry etching may include physical etching, chemical etching, and reactive ion etching, etc.

In step S3, a first metal barrier layer 106 is formed on the exposed first conductive structure 101. The first metal barrier layer 106 may, for example, include a layered structure, such as a first metal layer and a second metal layer. The first metal layer includes a plurality of stacked layers of titanium layer and platinum layer, where the titanium layer and platinum layer are arranged alternately with each other. The number of the stacked layers is 1 to 5, preferably 3. The thickness of the titanium layer is 100 to 300 angstroms, preferably 200 angstroms. The thickness of the platinum layer is 100 to 300 angstroms, preferably 200 angstroms. The second metal layer is made of titanium. The thickness of the second metal layer is 200 to 400 angstroms, preferably 300 angstroms. 1 angstrom = 1 × 10^(-10) meters. The formation methods of the first metal barrier layer 106 include, for example: chemical vapor deposition (CVD), physical vapor deposition (PVD), atomic layer deposition (ALD), electroplating, chemical plating, etc. When the first metal barrier layer 106 is a multilayer structure, the above methods may be performed multiple times, such as multiple depositions, multiple plating steps, etc.

As shown in FIG. 4C, in step S4, an insulating layer 103 is formed on the passivation layer 101 and the first metal barrier layer 106. Methods for forming the insulating layer 103 include, for example: coating, chemical vapor deposition (CVD), physical vapor deposition (PVD), thermal oxidation, sol-gel, electrodeposition, printing, etc.

As shown in FIG. 4D, in step S5, the insulating layer 103 is etched to form a through-hole, where the bottom of the through-hole 108 are aligned with the first metal barrier layer 106. Methods for forming the through-hole 108 include, for example: laser drilling, chemical vapor deposition (CVD), ion implantation, reactive ion etching (RIE), and deep reactive ion etching (DRIE), etc.

As shown in FIG. 4E, in step S6, filling metal 105 is deposited in the through-hole 108. Methods for depositing the filling metal 105 include, for example: electroplating, chemical plating, chemical vapor deposition (CVD), physical vapor deposition (PVD), etc.

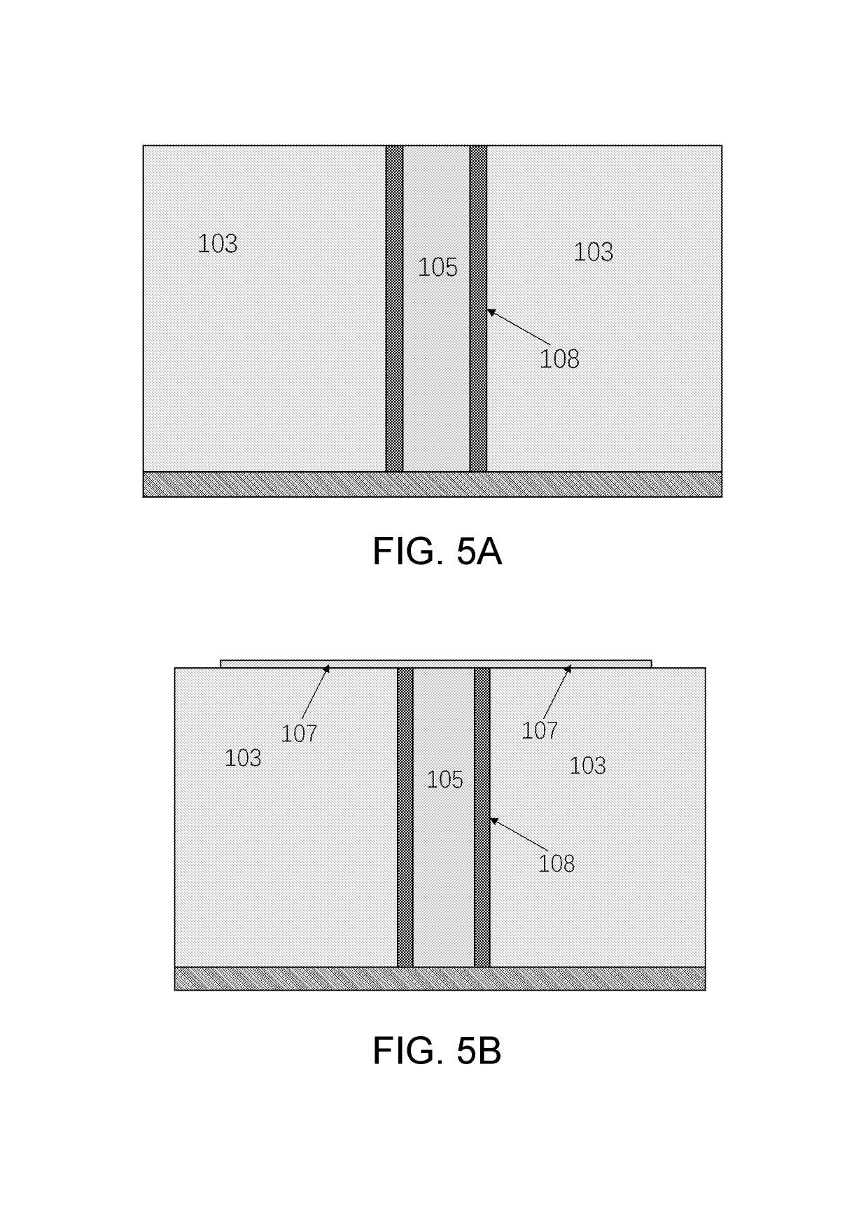

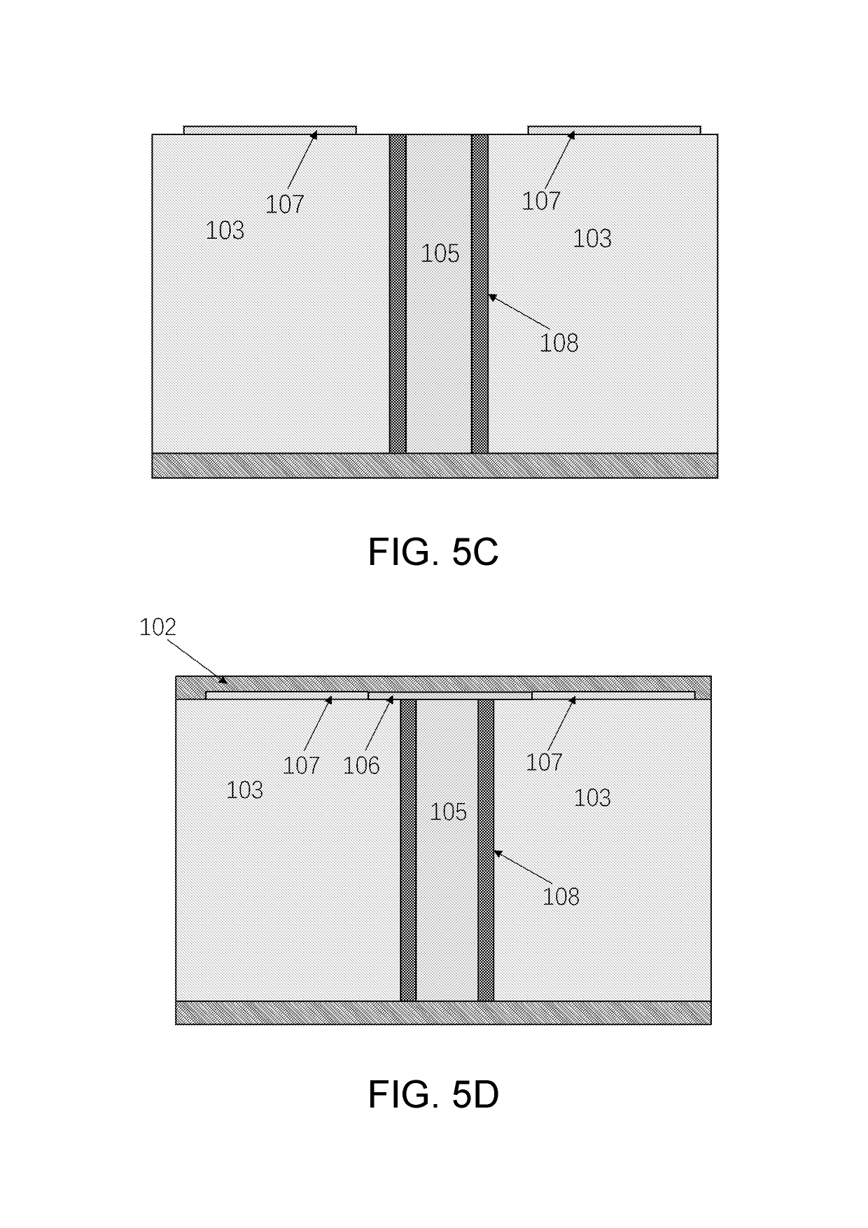

FIGS. 5A-5D illustrate a second embodiment of a method for forming a through-hole contact portion according to the present disclosure.

As shown in FIG. 5A, in step S1, through-hole 108 is provided, where the through-hole 108 is formed in the insulating layer 103 and has filling metal 105.

As shown in FIG. 5B, in step S2, a passivation layer 107 is formed on the top of the through-hole 108.

As shown in FIG. 5C, in step S3, a part of the passivation layer 107 is removed to expose the filling metal 105 in the through-hole 108.

As shown in FIG. 5D, in step S4, a first metal barrier layer 106 is formed on the exposed filling metal 105, and a third conductive structure 102 is formed on the first metal barrier layer. The first metal barrier layer 106 may, for example, include a layered structure, such as a first metal layer and a second metal layer. The first metal layer includes a plurality of stacked layers of titanium layer and platinum layer, where the titanium layer and platinum layer are arranged alternately with each other. The number of the stacked layers is 1 to 5, preferably 3. The thickness of the titanium layer is 100 to 300 angstroms, preferably 200 angstroms. The thickness of the platinum layer is 100 to 300 angstroms, preferably 200 angstroms. The second metal layer is made of titanium. The thickness of the second metal layer is 200 to 400 angstroms, preferably 300 angstroms. 1 angstrom = 1 × 10⁻¹⁰ meters. When the first metal barrier layer 106 is a multilayer structure, the above methods may be performed multiple times, such as multiple depositions, multiple plating steps, etc.

Although some embodiments of the present disclosure have been described in the present application, however, those skilled in the art will appreciate that these embodiments are merely illustrated as examples. Numerous variation schemes, alternative schemes, and improvement schemes may be conceived by those skilled in the art in light of the teachings of the present disclosure without departing from the scope of the present disclosure. The appended claims are intended to define the scope of the present disclosure and thus encompass methods and structures within the scope of these claims themselves and their equivalent variations.

What is claimed is:

1. A through-hole contact portion for a micro-LED, wherein the through-hole contact portion is configured to electrically connect a first conductive structure with a second conductive structure, wherein the first conductive structure is located below the through-hole contact portion and the second conductive structure is located above the through-hole contact portion, wherein the through-hole contact portion comprises:
a through-hole formed in an insulating layer and having a hollow cavity;
filling metal arranged in the hollow cavity of the through-hole for conducting electricity; and
a first metal barrier layer arranged between a bottom of the through-hole and the first conductive structure and/or between a top of the through-hole and the second conductive structure to block diffusion of the filling metal.

2. The through-hole contact portion according to claim 1, wherein a width of the first metal barrier layer is greater than a width of the bottom of the through-hole.

3. The through-hole contact portion according to claim 1, further comprising:
a second metal barrier layer arranged between an inner wall of the through-hole and the filling metal.

4. The through-hole contact portion according to claim 1, wherein a diameter of the through-hole is 0.2μm to 1 μm, and a height of the through-hole is 2μm to 5 μm.

5. The through-hole contact portion according to claim 3, wherein the first metal barrier layer and/or the second metal barrier layer comprise:
a first metal layer comprising a plurality of stacked layers of a titanium layer and a platinum layer, wherein the titanium layer and the platinum layer are arranged alternately with each other; and
a second metal layer made of titanium.

6. The through-hole contact portion according to claim 5, wherein the number of the stacked layers is 1 to 5.

7. The through-hole contact portion according to claim 6, wherein:
a thickness of the titanium layer is 100 to 300 angstroms; and/or
a thickness of the platinum layer is 100 to 300 angstroms; and/or
a thickness of the second metal layer is 200 to 400 angstroms.

8. The through-hole contact portion according to claim 1, further comprising:
a passivation layer arranged between the through-hole and the first conductive structure,and/or the second conductive structure and exposing the first metal barrier layer.

9. The through-hole contact portion according to claim 8, wherein:
a breakdown field strength of the passivation layer is not less than 1x10⁷ V/cm; or
a breakdown field strength of the passivation layer is not less than 6×10⁸ V/cm.

10. The through-hole contact portion according to claim 1, wherein a ratio of a cross-sectional length of the first metal barrier layer to a diameter of the through-hole is 1.2 to 1.8.

11. The through-hole contact portion according to of claim 1, wherein offset between a centerline of the through-hole and a centerline of the first conductive structure is 0.1 to 0.3 μm.

12. The through-hole contact portion according to claim 1, wherein the through-hole contact portion is configured to electrically connect a light-emitting mesa with a drive circuit.

13. A micro-LED chip, comprising:
a drive circuit;
a plurality of micro-LEDs, wherein each of the micro-LEDs comprises a light-emitting mesa arranged on the drive circuit and configured to emit a first light; and
the through-hole contact portion according to claim 1, which is configured to electrically connect the light-emitting mesa with the drive circuit.

14. The micro-LED chip according to claim 13, wherein:
a metal layer is arranged on a surface of the drive circuit, and a plurality of through-hole contact portions are arranged on the drive circuit, and the through-hole contact portions are electrically connected with the metal layer, and the micro-LEDs are bonded onto the drive circuit through a bottom conductive bonding layer, and the light-emitting mesa corresponds to one of the through-hole contact portions, and the light-emitting mesa comprises a first epitaxial layer, a light-emitting layer, and a second epitaxial layer deposited in sequence; and
the micro-LED further comprises:
a first electrode electrically connected with the through-hole contact portions;
a passivation isolation layer covering a surface of the light-emitting mesa but exposing at least a part of the second epitaxial layer;
a transparent conductive layer arranged on a surface of the passivation isolation layer and in electrical contact with the first epitaxial layer; and
a second electrode arranged on a surface of the transparent conductive layer.

15. The micro-LED chip according to claim 14, wherein the second electrode is a ring-shaped reflective electrode arranged around the light-emitting mesa.

16. The micro-LED chip according to claim 14, wherein a material of the second epitaxial layer is a material layer of a second conductivity type comprising two or more elements of Ga, N, As, Al, In, and P, and the first epitaxial layer is a material layer of a first conductivity type comprising at least two or more elements of Ga, N, As, Al, In, and P, wherein the first conductivity type is different from the second conductivity type.

17. A micro-LED chip according to claim 14, wherein there is an electron blocking layer on a first side of the light-emitting layer, and the first side is a side along which electrons migrate out of the light-emitting layer.

18. A micro-LED chip comprising:
an upper stacked layer, which comprises:
a first insulating layer;
a light-emitting mesa configured to emit light, wherein a top surface area of the light-emitting mesa is greater than a bottom surface area of the light-emitting mesa; and
a first through-hole contact portion constructed according to claim 1 and electrically connected with a bottom of the light-emitting mesa and passing through the first insulating layer, wherein the first insulating layer is configured to accommodate the light-emitting mesa and the first through-hole contact portion; and
a lower stacked layer, which comprises:
a second insulating layer;
a second through-hole contact portion constructed according to claim 1 and passing through the second insulating layer, wherein the second insulating layer is configured to accommodate the second through-hole contact portion; and
a drive backplane electrically connected with the second through-hole contact portion, wherein the lower stacked layer is bonded with the upper stacked layer through hybrid bonding, such that the first through-hole contact portion is bonded with the second through-hole contact portion and the first insulating layer is bonded with the second insulating layer.

19. A method for forming a through-hole contact portion, comprising the following steps:
providing a first conductive structure;
forming a passivation layer on the first conductive structure;
removing a part of the passivation layer to expose the first conductive structure;
forming a first metal barrier layer on the exposed first conductive structure;
forming an insulating layer on the passivation layer and the first metal barrier layer;
etching the insulating layer to form a through-hole, wherein a bottom of the through-hole is opposed to the first metal barrier layer; and
depositing filling metal in the through-hole.

20. The method according to claim 19, further comprising the following steps:
before depositing metal in the through-hole, forming a second metal barrier layer on an inner wall of the through-hole.
